(19) United States
(12) Patent Application Publication
(10) Pub. No.: US 2026/0089429 A1
(43) Pub. Date: Mar. 26, 2026

(54) FUNCTIONAL BOX ASSEMBLY, HEADPHONE, AND HEADPHONE SYSTEM

(71) Applicant: SUUNTO SPORTS TECHNOLOGY (DONGGUAN) CO., LTD., Dongguan (CN)

(72) Inventors: Junlin CHEN, Dongguan (CN); Zhonglin ZHANG, Dongguan (CN)

(21) Appl. No.: 19/403,283

(22) Filed: Nov. 28, 2025

Related U.S. Application Data
(63) Continuation of application No. PCT/CN2025/117797, filed on Aug. 29, 2025.

(30) Foreign Application Priority Data
Aug. 30, 2024 (CN) 202422134383.3

(51) Int. Cl. H04R 1/10; H05K 5/00; H05K 5/02; H05K 5/06

(52) U.S. Cl. CPC H04R 1/1041; H04R 1/1025; H05K 5/0017; H05K 5/0086; H05K 5/0247; H05K 5/061; H04R 2460/13

(57) ABSTRACT

Provided is a functional box assembly, including a box body and a button. The box body has a control region configured for installing the button. The control region is provided with at least two button regions. The button includes at least two trigger portions corresponding to the at least two button regions. The box body and the button are connected through a spacing portion, such that the at least two trigger portions and the at least two button regions are spaced apart from each other. The spacing portion is located between two adjacent button regions of the at least two button regions. The button is rotatable around the spacing portion to bring one of the at least two trigger portions into contact with a corresponding button region of the at least two button regions.

### CROSS-REFERENCE TO RELATED APPLICATIONS

This application is a continuation of International Application No. PCT/CN2025/117797, filed on Aug. 29, 2025, which claims priorities to Chinese Patent Applications No. 202422134383.3, filed on Aug. 30, 2024, the entire contents of which are incorporated herein by reference.

### FIELD

The present disclosure relates to the technical field of headphones, and in particular, to a functional box assembly, a headphone, and a headphone system.

### BACKGROUND

A functional box assembly usually includes a functional box and a button disposed at the functional box. A user may regulate a volume and the like by manipulating the button. The button usually includes two connected trigger portions. Pressing one of the two trigger portions may increase the volume, and pressing the other one of the two trigger portions may decrease the volume.

### SUMMARY

Embodiments of the present disclosure provide a functional box assembly, a headphone, and a headphone system.

The functional box assembly according to the embodiments of the present disclosure includes a box body and a button. The box body has a control region configured for installing a button. The control region is provided with at least two button regions. The button is disposed in the control region. The button includes at least two trigger portions corresponding to the at least two button regions. The box body and the button are connected through a spacing portion, such that the at least two trigger portions and the at least two button regions are spaced apart from each other. The spacing portion is located between two adjacent button regions of the at least two button regions. The button is rotatable around the spacing portion to bring one of the at least two trigger portions into contact with a corresponding button region of the at least two button regions.

In some embodiments, the control region is provided with a supporting portion extending from a sidewall of the box body and defining a mounting hole. The supporting portion includes a supporting body and the spacing portion protruding from the supporting body toward the button. One spacing portion is provided. The one spacing portion spans the control region in a width direction of the button.

In some embodiments, the control region is provided with a supporting portion extending from a sidewall of the box body and defining a mounting hole. The supporting portion includes a supporting body and the spacing portion protruding from the supporting body toward the button. Two spacing portions are provided. The two spacing portions are spaced apart from each other and arranged at the supporting body in the width direction of the button.

In some embodiments, the functional box assembly further includes a waterproof member disposed in the control region. The waterproof member and the supporting body are integrally formed through a two-color injection molding, an opening of the mounting hole is covered by the waterproof member, and the opening toward an interior of the box body.

In some embodiments, a hardness of the waterproof member is less than a hardness of the box body.

In some embodiments, the waterproof member is made of polymer; and the box body is made of polymer.

In some embodiments, the waterproof member includes two waterproof sub-members connected to each other. One of the two waterproof sub-members corresponds to one of the at least two button regions in a thickness direction of the button; and when one of the at least two trigger portions contacts a corresponding button region of the at least two button regions, a corresponding waterproof sub-member of the two waterproof sub-members is deformed.

In some embodiments, each of the two waterproof sub-members includes a first waterproof portion located in the mounting hole and a second waterproof portion surrounding and connected to a periphery of the first waterproof portion. The second waterproof portion is embedded in and connected to the supporting body. When a corresponding one of the at least two trigger portions apply a force to the first waterproof portion, the first waterproof portion is deformed under the force, and the second waterproof portion remains fixedly connected to the supporting body.

In some embodiments, the supporting body includes a first protrusion and a second protrusion that are arranged in a stepped manner in the thickness direction of the button. The first protrusion is closer to an outside of the box body than the second protrusion, and the spacing portion is arranged at a side of the first protrusion. The side of the first protrusion is the second protrusion.

In some embodiments, the supporting body has an injection hole at least penetrating the second protrusion. At least a portion of the second waterproof portion is located in the injection hole.

In some embodiments, the first protrusion includes a protrusion body that is of annular shape and two protruding extension portions. The two protruding extension portions protrude from the protrusion body toward a center of the protrusion body. The spacing portion is disposed at the two protruding extension portions; and the second protrusion includes a first sub-protrusion that is of annular shape, a second sub-protrusion that is of annular shape, and a connection sub-protrusion connecting the first sub-protrusion to the second sub-protrusion. The first sub-protrusion, the connection sub-protrusion, and the second sub-protrusion are arranged in a length direction of the button. At least a portion of the connection sub-protrusion is opposite to the two protruding extension portions in the thickness direction of the button. Each of the first sub-protrusion, the connection sub-protrusion, and the second sub-protrusion has the injection hole.

In some embodiments, the injection hole includes a first injection hole formed at the first sub-protrusion and the second sub-protrusion and a second injection hole disposed at the connection sub-protrusion. At least a portion of the second waterproof portion is located in the first injection hole. The second injection hole is located between the two waterproof sub-members, and at least a portion of a junction of the two waterproof sub-members is located in the second injection hole.

In some embodiments, the first waterproof portion includes a first side and a second side that are opposite to each other in a thickness direction of the waterproof member. The first side of the first waterproof portion is closer to an outside of the box body than the second side of the first waterproof portion. The first side of the first waterproof portion includes a mounting post. The mounting post has an insertion hole; and the button includes a first side and a second side that are opposite to each other in the thickness direction of the button. The first side of the button is closer to the outside of the box body than the second side of the button. The second side of the button is provided with a connection post. The connection post extends into the insertion hole of the mounting post when the button is mounted at the waterproof member.

In some embodiments, a center of the insertion hole is located at a length mid-plane and a width mid-plane of the waterproof sub-member.

In some embodiments, a plurality of mounting posts is provided. The plurality of mounting posts has a plurality of insertion holes; and a plurality of connection posts is provided. The plurality of connection posts is inserted into the plurality of insertion holes, respectively.

In some embodiments, the plurality of mounting posts are arranged sequentially in a length direction of the waterproof member or a width direction of the waterproof member; and adjacent mounting posts of the plurality of mounting posts share one sidewall. A sidewall of each of at least one of the plurality of mounting posts has a notch that penetrates an inner side and an outer side of the corresponding mounting post and is in communication with the corresponding insertion hole.

In some embodiments, at one waterproof sub-member of the two waterproof sub-members, the notch is disposed at each of the plurality of mounting posts. An extending direction of the notch is the same as the length direction of the waterproof member or the width direction of the waterproof member.

In some embodiments, the first side of the button is provided with a thinned portion located at a connection between two button regions of the at least two button regions.

The headphone according to the embodiments of the present disclosure includes the functional box assembly described in the above embodiments.

In some embodiments, the headphone includes a bone conduction headphone and an air conduction headphone.

The headphone system according to the embodiments of the present disclosure includes the headphone described in the above embodiments and a charging case configured to charge the headphone.

Additional aspects and advantages of the present disclosure will be provided in part in the following description, or will become apparent in part from the following description, or can be learned from practicing of the present disclosure.

### BRIEF DESCRIPTION OF THE DRAWINGS

The above and/or additional aspects and advantages of the present disclosure will become more apparent and more understandable from the following description of embodiments taken in conjunction with the accompanying drawings, in which:

FIG. 1 is a schematic perspective view of a headphone according to some embodiments of the present disclosure.

FIG. 2 is a schematic perspective view of a functional box assembly in the headphone of FIG. 1.

FIG. 3 is a schematic cross-sectional view of the functional box assembly of FIG. 2 taken along line III-III.

FIG. 4 is a schematic perspective exploded view of the functional box assembly of FIG. 2.

FIG. 5 is a schematic perspective exploded view of the functional box assembly of FIG. 2.

FIG. 6 is a schematic perspective view of a headphone system according to some embodiments of the present disclosure.

### DETAILED DESCRIPTION

In order to clarify the above-mentioned objects, features, and advantages of the present disclosure, specific implementations of the present disclosure are described in detail below in conjunction with the accompanying drawings. In the following description, many specific details are provided to facilitate full understanding of the present disclosure. However, the present disclosure can be implemented in various manners other than those described herein, and similar improvements can be made by those skilled in the art without contradicting the intent of the present disclosure. Therefore, the present disclosure is not limited by specific implementations disclosed below.

In the description of the present disclosure, it needs to be understood that, orientation or position relationship indicated by terms such as “center”, “longitudinal”, “lateral”, “length”, “width”, “thickness”, “above”, “below”, “front”, “back”, “left”, “right”, “vertical”, “horizontal”, “top”, “bottom”, “in”, “out”, “clockwise”, “anti-clockwise”, “axial”, “radial” and “circumferential” is based on the orientation or position relationship illustrated in the accompanying drawings, and is merely for the convenience of describing the present disclosure and simplifying the description, rather than indicating or implying that the associated device or element must have a specific orientation, or be constructed and operated in a specific orientation, and therefore cannot be understood as a limitation on the present disclosure.

In addition, the terms “first” and “second” are only used for descriptive purposes, and cannot be understood as indicating or implying relative importance or implicitly indicating the number of indicated technical features. Therefore, the features associated with “first” and “second” may explicitly or implicitly include at least one of the features. In the description of the present disclosure, “plurality of” means at least two, such as two, three, etc., unless otherwise specifically defined.

In the present disclosure, unless otherwise clearly specified and limited, terms such as “install”, “connect”, “connect to”, “fix”, and the like should be understood in a broad sense. For example, it may be a fixed connection or a detachable connection or connection as one piece; mechanical connection or electrical connection; direct connection or indirect connection through an intermediate; internal communication of two components or the interaction relationship between two components. For those of ordinary skill in the art, the specific meanings of the above terms in the present disclosure can be interpreted depending on specific situations.

In the present disclosure, unless expressly stipulated and defined otherwise, the first feature “on” or “under” the second feature may mean that the first feature is in direct contact with the second feature, or the first and second features are in indirect contact through an intermediate. Moreover, the first feature “above” the second feature may mean that the first feature is directly above or obliquely above the second feature, or simply mean that the level of the first feature is higher than that of the second feature. The first feature “below” the second feature may mean that the first feature is directly below or obliquely below the second feature, or simply mean that the level of the first feature is smaller than that of the second feature.

It should be noted that when an element is referred to as being “fixed to” or “disposed at” another element, it can be directly at the other element or a centered element may also occur. When an element is considered to be “connected to” another element, it may be directly connected to the other element or a centered element may occur simultaneously. As used herein, the terms “vertical”, “horizontal”, “over”, “below”, “left”, “right”, and similar expressions are for illustrative purposes only and are not meant to be the only implementations.

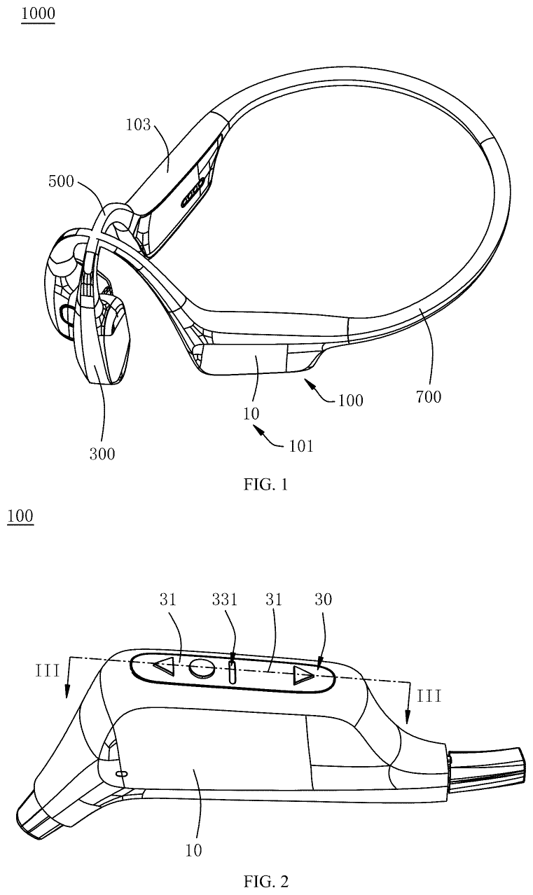

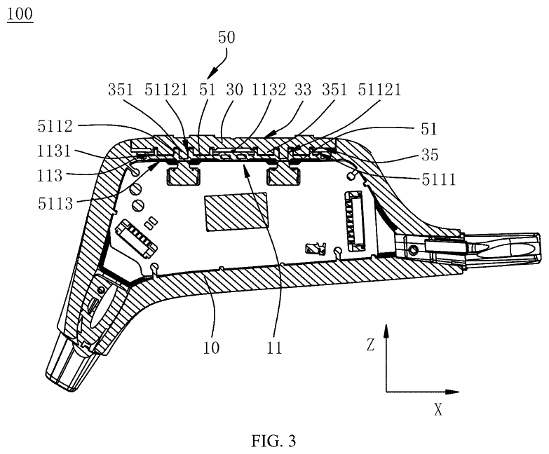

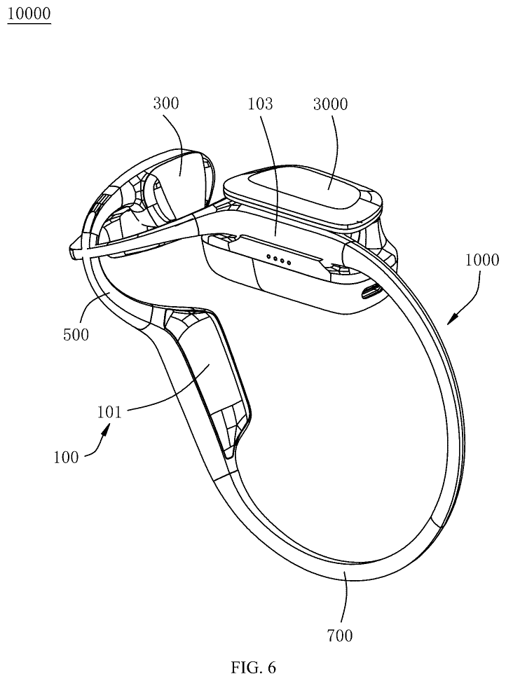

A functional box assembly usually includes a functional box and a button disposed at the functional box. A user may regulate a volume and the like by manipulating the button. The button usually includes two connected trigger portions. Pressing one of the two trigger portions may increase the volume, and pressing the other one of the two trigger portions may decrease the volume. However, since the user usually performs a blind operation on the button which is small in size, the two trigger portions are prone to linkage, causing both volume increase and volume decrease to be triggered simultaneously, thus making volume regulation impossible. To solve this problem, the embodiments of the present disclosure provide a functional box assembly 100 (shown in FIG. 2), a headphone 1000 (shown in FIG. 1), and a headphone system 10000 (shown in FIG. 6).

Referring to FIG. 1, the headphone 1000 according to the embodiments of the present disclosure includes the functional box assembly 100. In some embodiments, the headphone 1000 includes a bone conduction headphone 1000 and an air conduction headphone 1000.

The bone conduction headphone 1000 uses human bones as a medium, and converts sound into mechanical vibrations, which transmit sound waves through the human bones, such that the user hears the sound. The sound of the bone conduction headphone 1000 acts on the bones, and long-term use of the bone conduction headphone 1000 will not cause significant damage to an eardrum of user's ear, which can effectively protect hearing of the user. The air conduction headphone 1000 transmits sound through air vibrations, and has better sound quality and penetration. The headphone 1000 of the present disclosure is described by taking the bone conduction headphone 1000 as an example.

The functional box assembly 100 includes a battery box assembly 103 and/or a control box assembly 101. In some embodiments, the functional box assembly 100 may include the control box assembly 101. The control box assembly 101 may be configured to control power-on and power-off of the headphone 1000 and regulate a volume of the headphone 1000. In other embodiments, the functional box assembly 100 may include the battery box assembly 103. The battery box assembly 103 includes a battery configured to supply power to other components of the headphone 1000, such that the headphone 1000 operates normally. In yet another embodiment, the functional box assembly 100 may include the battery box assembly 103 and the control box assembly 101. The present disclosure is described by taking the control box assembly 101 as being the functional box assembly 100 as an example.

Referring to FIG. 1, in some embodiments, the headphone 1000 further includes an ear hook 500, a rear headband 700, and a transducer box assembly 300. The ear hook 500 is configured to connect the battery box assembly 103 and the transducer box assembly 300, and to connect the control box assembly 101 and the transducer box assembly 300. The rear headband 700 is configured to connect the battery box assembly 103 and the control box assembly 101. When the headphone 1000 is worn by the user, the rear headband 700 of the headphone 1000 is worn on the head, and the ear hook 500 of the headphone 1000 is worn behind the ear, which can improve wearing stability of the headphone 1000. Even when the user is outdoors or exercising, the headphone 1000 is not easy to fall off. When the headphone 1000 is in use, the transducer box assembly 300 may be in contact with the skin of the user and may generate mechanical vibrations to allow the user to hear sound.

Referring to FIG. 2 to FIG. 4, the functional box assembly 100 according to the embodiments of the present disclosure includes a box body 10 and a button 30. The box body 10 has a control region 11 configured for installing the button 30, and the control region 11 is provided with at least two button regions 111. The button 30 is disposed in the control region 11 and includes at least two trigger portions 31 corresponding to the at least two button regions 111. The box body 10 and the button 30 are connected through a spacing portion 1132, such that the at least two trigger portions 31 and the at least two button regions 111 are spaced apart from each other. The spacing portion 1132 is located between two adjacent button regions 111 of the at least two button regions 111, and the button 30 is rotatable around the spacing portion 1132 to bring one of the at least two trigger portions 31 into contact with a corresponding button region 111 of the at least two button regions 111.

In an embodiment, the box body 10 is configured to mount other components of the functional box assembly 100. For example, a circuit board, the button 30, and other components may be mounted in the box body 10. The control region 11 is configured to mount a control component of the functional box assembly 100 (such as the button 30) therein.

Referring to FIG. 2 to FIG. 4, the button 30 is mounted in the control region 11, and at least a portion of the button 30 is exposed from the control region 11 to facilitate the user's manipulation of the button 30. Exemplarily, the user may control the power-on and power-off of the headphone 1000 through the button 30, regulate the volume of the headphone 1000 through the button 30, and switch audio by manipulating the button 30. The present disclosure is described by taking the button 30 as a volume button 30 capable of controlling the volume of the headphone 1000 as an example. At this time, the button 30 may include two trigger portions 31, and the control region 11 may include two button regions 111. The two trigger portions 31 correspond to the two button regions 111, respectively. When the user presses one of the two trigger portions 31 and the trigger portion 31 is in contact with its corresponding button region 111, the volume of the headphone 1000 may be increased. When the user presses the other one of the two trigger portions 31 and the trigger portion 31 is in contact with its corresponding button region 111, the volume of the headphone 1000 may be decreased.

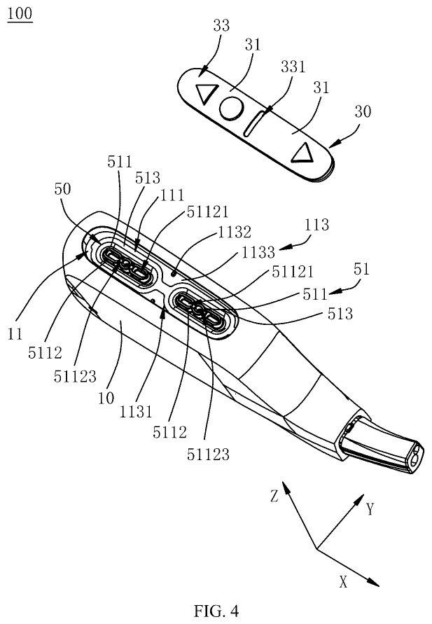

Referring to FIG. 3 and FIG. 4, the spacing portion 1132 may be disposed at the box body 10 and located between the two button regions 111, i.e., in a thickness direction Z of the button 30, the spacing portion 1132 is also located between the two trigger portions 31. When no external force is applied to the button 30, the two trigger portions 31 of the button 30 and the two button regions 111 are spaced apart from each other. When the user presses a region between the two trigger portions 31, this region abuts with the spacing portion 1132. In this way, the region cannot be pressed down, which can avoid a problem of the linkage between the two trigger portions 31 caused by pressing the region between the two trigger portions 31. When the user applies an external force to one of the trigger portions 31, the button 30 may rotate with the spacing portion 1132 as a fulcrum. At this time, the trigger portion 31, when subjected to force, rotates downwards to be in contact with the corresponding button region 111, which can regulate the volume of the headphone 1000. The other trigger portion 31 rotates upwards and moves further away from the corresponding button region 111, i.e., the other trigger portion 31 is not in contact with the corresponding button region 111. In this way, a problem that the two trigger portions 31 are linked to be in contact with the two button regions 111 simultaneously can be effectively avoided. When the two trigger portions 31 are in contact with the two button regions 111 simultaneously, the button 30 cannot regulate the volume of the headphone 1000.

When the spacing portion 1132 is located between the two button regions 111, the spacing portion 1132 may be similar to a fulcrum of a seesaw, and the button 30 may be similar to the seesaw. When one trigger portion 31 is pressed, the spacing portion 1132 enables the trigger portion 31 to be pressed independently, avoiding a case where the other trigger portion 31 is pressed together due to the linkage of the two trigger portions 31. In this way, the pressed trigger portion 31 can accurately trigger the corresponding button region 111 and effectively regulate the volume of the headphone 1000.

In the functional box assembly 100 according to the embodiments of the present disclosure, the box body 10 and the button 30 are connected through a spacing portion 1132, such that the at least two trigger portions 31 and the at least two button regions 111 are spaced apart from each other. The spacing portion 1132 is located between two adjacent button regions 111 of the at least two button regions 111. When the user presses one of the trigger portions 31, the button 30 may rotate around the spacing portion 1132 to bring the trigger portions 31 into contact with the corresponding button region 111, to regulate a function of the headphone 1000. When the button 30 rotates around the spacing portion 1132, the other trigger portion 31 may be spaced apart from the corresponding button region 111. Compared with an existing functional box assembly 100, the present disclosure is provided with the spacing portion 1132, which enables the trigger portions 31 to be pressed independently without the occurrence of linkage between the two trigger portions 31. In this way, a problem where the two trigger portions 31 are simultaneously in contact with the corresponding button regions 111, making it impossible to regulate the function of the headphone 1000, can be avoided.

The functional box assembly 100 is further described below with reference to the accompanying drawings.

Referring to FIG. 3 to FIG. 5, in some embodiments, the control region 11 is provided with a supporting portion 113 extending from a sidewall of the box body 10 and defining a mounting hole 1131. The supporting portion 113 includes a supporting body 1133 and the spacing portion 1132 protruding from the supporting body 1133 toward the button 30.

The supporting portion 113 is configured to support the button 30 and the waterproof member 50 of the functional box assembly 100. The mounting hole 1131 is configured to allow the button 30 to be in contact with the control component in the button region 111, to regulate the volume of the headphone 1000. The box body 10 is internally provided with a circuit board that may be provided with a volume-up switch and a volume-down switch. Each of a position of the volume-up switch and a position of the volume-down switch may correspond to a position of the mounting hole 1131. The volume-up switch is located in one button region 111, and the volume-down switch is located in the other button region 111. The button 30 is mounted at the supporting portion 113 and corresponds to the mounting hole 1131. When a trigger portion 31 for increasing the volume of the headphone 1000 is pressed, the button 30 may rotate relative to the spacing portion 1132. When the trigger portion 31 are in contact with the volume-up switch in its corresponding button region 111, the volume of the headphone 1000 may be effectively increased. When a trigger portion 31 for decreasing the volume of the headphone 1000 is pressed, the button 30 may rotate relative to the spacing portion 1132. When the trigger portion 31 is in contact with the volume-down switch in its corresponding button region 111, the volume of the headphone 1000 may be effectively decreased.

The supporting body 1133 and the spacing portion 1132 may be of an integral structure or a split structure. When the supporting body 1133 and the spacing portion 1132 are of an integral structure, the supporting body 1133 and the spacing portion 1132 may be integrally formed, which makes a processing step of the box body 10 simple and a connection between the supporting body 1133 and the spacing portion 1132 relatively stable. When the supporting body 1133 and the spacing portion 1132 are of a split structure, the supporting body 1133 and the spacing portion 1132 are connected detachably or non-detachably. The detachable connection manner includes, but is not limited to, a threaded connection, a screw connection, or a snap connection. The non-detachable connection manner includes, but is not limited to, welding, adhesive bonding, or an interference fit.

Referring to FIG. 3 to FIG. 5, further, in some embodiments, the functional box assembly 100 further includes a waterproof member 50 disposed in the control region 11. The waterproof member 50 and the supporting body 1133 are integrally formed through a two-color injection molding, and an opening of the mounting hole 1131 is covered by the waterproof member 50. The opening faces towards an interior of the box body 10.

The waterproof member 50 is configured to prevent external liquid from entering the interior of the box body 10 through the mounting hole 1131, to prevent the external liquid from affecting normal operation of a component inside the box body 10. The waterproof member 50 is connected to the supporting body 1133 and covers the mounting hole 1131. The waterproof member 50 and the supporting body 1133 in the present disclosure are made of different materials. When the waterproof member 50 and the supporting body 1133 are integrally formed through the two-color injection molding, the connection between the waterproof member 50 and the supporting body 1133 is relatively tight, which can effectively prevent the external liquid from entering the interior of the box body 10 through a gap between the waterproof member 50 and the supporting body 1133, making a good waterproof effect of the functional box assembly 100. Moreover, a connection strength between the waterproof member 50 and the supporting body 1133 is relatively high, and the waterproof member 50 is not easy to disengage from the supporting body 1133.

Referring to FIG. 3 to FIG. 5, in some embodiments, a hardness of the waterproof member 50 is less than a hardness of the box body 10. When the button 30 is mounted at the box body 10, the button 30 corresponds to the waterproof member 50. When one trigger portion 31 is pressed to regulate the volume of the headphone 1000, the trigger portion 31 may be in contact with a corresponding volume switch on the circuit board through the waterproof member 50. In response to the hardness of the waterproof member 50 being less than the hardness of the box body 10, the waterproof member 50 may be deformed when subjected to the external force. When the trigger portion 31 is pressed, the trigger portion 31 may apply a pressure to the waterproof member 50, such that the waterproof member 50 deforms. In this way, the trigger portion 31 can be in contact with the corresponding volume switch on the circuit board through the waterproof member 50 to regulate the volume of the headphone 1000. In response to the hardness of the waterproof member 50 is greater than the hardness of the box body 10, when the trigger portion 31 is pressed and applies a pressure to the waterproof member 50, the waterproof member 50 is not easy to deform, making it difficult for the trigger portion 31 to be in contact with the corresponding volume switch on the circuit board through the waterproof member 50. Therefore, the volume regulation of the headphone 1000 is not sensitive enough, resulting in poor user experience.

Referring to FIG. 3 to FIG. 5, preferably, in some embodiments, the waterproof member 50 is made of polymer, and the box body 10 is made of polymer. When the box body 10 is made of polymer, the box body 10 has a relatively high strength and is not easy to be damaged. At this time, the supporting body 1133 also has a relatively high strength. When the trigger portion 31 is pressed and applies a certain pressure to the supporting body 1133, the supporting body 1133 is not easy to deform or be damaged, allowing for a long service life of the box body 10. When the waterproof member 50 is made of polymer, the occurrence of deformation of the polymer may be facilitated, which can facilitate the corresponding volume switch to be in contact with the circuit board by the trigger portion 31 through the waterproof member 50. The user may regulate the volume without the need to apply a large pressure to the trigger portion 31, resulting in good user experience. The polymer may be, but is not limited to, rubber, silica gel, thermoplastic elastomer, or polyvinyl chloride.

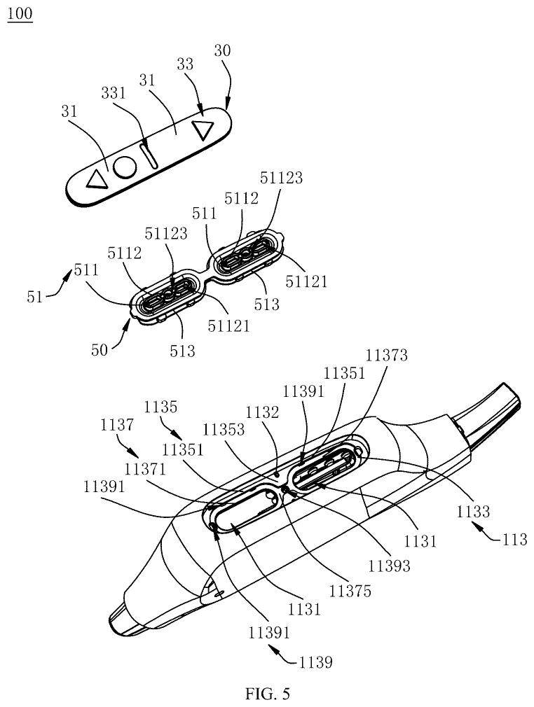

Referring to FIG. 4 and FIG. 5, in some embodiments, one spacing portion 1132 is provided. The one spacing portion 1132 spans the control region 11 in a width direction Y of the button 30. At this time, the supporting portion 113 is simple in structure and easy to process. Moreover, the spacing portion 1132 may play a good fulcrum role for the button 30. When one trigger portion 31 is pressed, the other trigger portion 31 may be effectively prevented from being pressed in a linkage manner. In other embodiments, two spacing portions 1132 are provided. The two spacing portions 1132 are spaced apart from each other and arranged at the supporting body 1133 in the width direction Y of the button 30. At this time, since the waterproof member 50 is of an integral structure, a spacing between the two spacing portions 1132 may be used for mounting the waterproof member 50, i.e., the spacing between the two spacing portions 1132 is used for making way for the waterproof member 50. In the present disclosure, both of the two spacing portions 1132 are spaced apart from the waterproof member 50.

Referring to FIG. 3 to FIG. 5, in some embodiments, the waterproof member 50 includes two waterproof sub-members 51 connected to each other. One of the two waterproof sub-members 51 corresponds to one of the at least two button regions 111 in a thickness direction Z of the button 30. When one of the at least two trigger portions 31 is in contact with a corresponding button region 111 of the at least two button regions 111, a corresponding waterproof sub-member 51 of the two waterproof sub-members 51 is deformed.

One waterproof sub-member 51 corresponds to one trigger portion 31, and the other waterproof sub-member 51 corresponds to the other trigger portion 31. When one trigger portion 31 is pressed, the pressed trigger portion 31 may drive the corresponding waterproof sub-member 51 to deform. In this way, the trigger portion 31 can be in contact with the volume switch on the corresponding button region 111 through the waterproof sub-member 51 to realize the volume regulation.

Referring to FIG. 4 and FIG. 5, specifically, in some embodiments, each of the two waterproof sub-members 51 includes a first waterproof portion 511 located in the mounting hole 1131 and a second waterproof portion 513 surrounding and connected to a periphery of the first waterproof portion 511. The second waterproof portion 513 is embedded in and connected to the supporting body 1133. When a corresponding one of the at least two trigger portions 31 apply a force to the first waterproof portion 511, the first waterproof portion 511 is deformed under the force, and the second waterproof portion 513 remains fixedly connected to the supporting body 1133.

When the second waterproof portion 513 is embedded in and connected to the supporting body 1133, in the thickness direction Z of the button 30, one part of the second waterproof portion 513 may be connected to a top surface of the supporting body 1133, another part of the second waterproof portion 513 may be connected to a bottom surface of the supporting body 1133, and yet another part of the second waterproof portion 513 may extend into an interior of the supporting body 1133. In this way, a connection strength between the second waterproof portion 513 and the supporting body 1133 is relatively high. The waterproof member 50 is not easy to disengage from the supporting body 1133 and has an excellent waterproof effect. The external liquid cannot easily enter the interior of the box body 10 through a gap between the second waterproof portion 513 (the waterproof member 50) and the supporting body 1133.

The first waterproof portion 511 is configured to deform under pressure to bring the trigger portion 31 into contact with the volume switch of the button region 111 through the first waterproof portion 511. The second waterproof portion 513 is configured to be fixedly connected to the supporting body 1133, to prevent the waterproof sub-member 51 from disengaging from the supporting body 1133 and to prevent the external liquid from entering the interior of the box body 10 through the mounting hole 1131. When the user applies the external force to the trigger portion 31, the trigger portion 31 applies a certain pressure on the waterproof sub-member 51. At this time, the first waterproof portion 511 may deform toward the interior of the box body 10 to some extent, while the second waterproof portion 513 still remains firmly connected to the supporting body 1133. In this way, the waterproof sub-member 51 is not easy to disengage from the supporting body 1133 even under the external force, allowing for a relatively tight connection between the waterproof sub-member 51 and the supporting body 1133.

Referring to FIG. 5, in some embodiments, the supporting body 1133 includes a first protrusion 1135 and a second protrusion 1137 that are arranged in a stepped manner in the thickness direction Z of the button 30. The first protrusion 1135 is closer to an outside of the box body 10 than the second protrusion 1137, and the spacing portion 1132 is arranged at a side of the first protrusion 1135. The side of the first protrusion 1135 is the second protrusion 1137.

Each of the first protrusion 1135 and the second protrusion 1137 extends from the sidewall of the box body 10. The second protrusion 1137 has an area greater than an area of the first protrusion 1135 and is closer to a center of the mounting hole 1131. When the second protrusion 1137 and the first protrusion 1135 are arranged in a stepped manner, a contact area between the supporting body 1133 and the waterproof member 50 is relatively large. After the supporting body 1133 and the waterproof member 50 are integrally formed through the two-color injection molding, the connection strength between the supporting body 1133 and the waterproof member 50 is relatively high, and the waterproof member 50 is not easy to disengage from the supporting body 1133.

Referring to FIG. 5, in some embodiments, the supporting body 1133 has an injection hole 1139 at least penetrating the second protrusion 1137. At least a portion of the second waterproof portion 513 is located in the injection hole 1139.

During the process where the supporting body 1133 and the waterproof member 50 are integrally formed through the two-color injection molding, molten polymer flows into the injection hole 1139 from each of an upper surface and a lower surface of the supporting body 1133. After the molten polymer solidifies, the waterproof member 50 is formed. At this time, the second waterproof portion 513 of the waterproof member 50 forms a tight embedded connection with the supporting body 1133. The second waterproof portion 513 will not deform or disengage from the supporting body 1133 under the external force, making the connection between the waterproof member 50 and the supporting body 1133 relatively stable. Moreover, the external liquid cannot easily enter the box body 10 through the mounting hole 1131, making a waterproof effect of the functional box assembly 100 better. The number of injection holes 1139 may be, but is not limited to, one, two, three, four, or more. When a plurality of injection holes 1139 are provided, the connection strength between the second waterproof portion 513 and the supporting body 1133 is relatively high.

Referring to FIG. 5, specifically, in some embodiments, the first protrusion 1135 includes a protrusion body 11351 that is of annular shape and two protruding extension portions 11353. The two protruding extension portions 11353 protrude from the protrusion body 11351 toward a center of the protrusion body 11351. The spacing portion 1132 is disposed at the two protruding extension portions 11353. The second protrusion 1137 includes a first sub-protrusion 11371 that is of annular shape, a second sub-protrusion 11373 that is of annular shape, and a connection sub-protrusion 11375 connecting the first sub-protrusion 11371 to the second sub-protrusion 11373. The first sub-protrusion 11371, the connection sub-protrusion 11375, and the second sub-protrusion 11373 are arranged in a length direction X of the button 30. At least a portion of the connection sub-protrusion 11375 is opposite to the two protruding extension portions 11353 in the thickness direction Z of the button 30. Each of the first sub-protrusion 11371, the connection sub-protrusion 11375, and the second sub-protrusion 11373 has the injection hole 1139.

At this time, at least a portion of the second waterproof portion 513 is located in the plurality of injection holes 1139. The second waterproof portion 513 forms a tight embedded connection with each of the first sub-protrusion 11371, the connection sub-protrusion 11375, and the second sub-protrusion 11373, resulting in an even tighter connection between the second waterproof portion 513 and the supporting body 1133. Therefore, the waterproof member 50 has an excellent waterproof effect, and is not easy to disengage from the supporting body 1133.

Referring to FIG. 5, in some embodiments, the injection hole 1139 includes a first injection hole 11391 disposed at the first sub-protrusion 11371 and the second sub-protrusion 11373 and a second injection hole 11393 disposed at the connection sub-protrusion 11375. At least a portion of the second waterproof portion 513 is located in the first injection hole 11391. The second injection hole 11393 is located between the two waterproof sub-members 51. At least a portion of a portion junction of the two waterproof sub-members 51 is located in the second injection hole 11393.

Referring to FIG. 5, the number of first injection holes 11391 on the first sub-protrusion 11371 may be, but is not limited to, one, two, three, or more. The number of first injection holes 11391 on the second sub-protrusion 11373 may also be, but is not limited to, one, two, three, or more. In the present disclosure, the number of first injection holes 11391 on the first sub-protrusion 11371 is the same as the number of first injection holes 11391 on the second sub-protrusion 11373. Exemplarily, the first sub-protrusion 11371 has five first injection holes 11391, and the second sub-protrusion 11373 also has five first injection holes 11391. When at least a portion of the second waterproof portion 513 is located in the plurality of first injection holes 11391, the connection between the second waterproof portion 513 and the supporting body 1133 is relatively tight, allowing for a good waterproof effect of the functional box assembly 100. The external liquid is difficult to enter the interior of the box body 10 through the gap between the waterproof member 50 and the supporting body 1133, and the waterproof member 50 is not easy to disengage from the supporting body 1133.

Referring to FIG. 5, the number of second injection holes 11393 may be, but is not limited to, one, two, three, or more. In the present disclosure, one second injection hole 11393 is disposed, making a structure of the supporting body 1133 relatively simple. When at least a portion of the connection between the two waterproof sub-members 51 is located in the second injection hole 11393, cooperation between the connection and the second injection hole 11393 may effectively prevent linkage of the two waterproof sub-members 51. When one trigger portion 31 is pressed, the trigger portion 31 may apply a certain pressure on the corresponding waterproof sub-member 51, causing the waterproof sub-member 51 to deform to some extent. With the cooperation between the connection of the two waterproof sub-members 51 and the second injection hole 11393, when the waterproof sub-member 51 deforms, the other waterproof sub-member 51 cannot deform together with the deformed one. In this way, it is possible to avoid a problem that the other waterproof sub-member 51 deforms and is mistakenly in contact with the volume switch in the corresponding button region 111, thus making mutual interference between the two waterproof sub-members 51 relatively small.

Referring to FIG. 3 to FIG. 5, further, in some embodiments, the first waterproof portion 511 includes a first side 5111 and a second side 5113 that are opposite to each other in a thickness direction Z of the waterproof member 50. The first side 5111 of the first waterproof portion is closer to an outside of the box body 10 than the second side 5113 of the first waterproof portion. The first side 5111 of the first waterproof portion includes a mounting post 5112 that has an insertion hole 51121. The button 30 includes a first side 33 and a second side 35 that are opposite to each other in the thickness direction Z of the button 30. The first side 33 of the button 30 is closer to the outside of the box body 10 than the second side 35 of the button 30. The second side 35 of the button 30 is provided with a connection post 351. The connection post 351 extends into the insertion hole 51121 of the mounting post 5112 when the button 30 is mounted at the waterproof member 50.

When the connection post 351 extends into the insertion hole 51121, the connection between the button 30 and the waterproof member 50 is relatively stable, and the button 30 is not easy to disengage from the waterproof member 50. At least part of the connection post 351 may correspond to the volume switch of the button region 111. In this way, when the trigger portion 31 is pressed, the at least part of the connection post 351 may drive the waterproof sub-member 51 to deform to bring the at least part of the connection post into contact with the volume switch of the button region 111 through the waterproof sub-member 51, which can facilitate the volume regulation of the headphone 1000.

Referring to FIG. 4 and FIG. 5, preferably, in some embodiments, a center of the insertion hole 51121 is located at a length mid-plane and a width mid-plane of the waterproof sub-member 51. At this time, the insertion hole 51121 is centrally disposed at the waterproof sub-member 51, and the connection post 351 on the trigger portion 31 may also be centered. When the external force is applied to the trigger portion 31, the force is more concentrated on a middle part of the trigger portion 31. In this way, the deformation of the waterproof sub-member 51 is also more concentrated on the middle part. Therefore, one the one hand, the connection post 351 on the trigger portion 31 can be better in contact with the volume switch of the corresponding button region 111 through the waterproof sub-member 51. On the other hand, a pulling force applied at a periphery of the waterproof sub-member 51 (the second waterproof portion 513) is relatively uniform, which can avoid a problem that a part of the second waterproof portion 513 bears a greater pulling force than other parts, resulting in easy damage to the second waterproof portion 513. When the second waterproof portion 513 is subjected to uniform force at each part of the second waterproof portion 513, a service life of the waterproof member 50 may be prolonged.

Referring to FIG. 3 to FIG. 5, in some embodiments, a plurality of mounting posts 5112 is provided. The plurality of mounting posts 5112 has a plurality of insertion holes 51121. A plurality of connection posts 351 is provided. The plurality of connection posts 351 is inserted into the plurality of insertion holes 51121, respectively. At this time, a plurality of connection points are formed between the button 30 and the first waterproof portion 511. In this way, the connection strength between the button 30 and the waterproof member 50 is higher, and the connection stability between the button 30 and the waterproof member 50 is better, which can further prevent the button 30 from disengaging from the waterproof member 50.

Referring to FIG. 3 to FIG. 5, in some embodiments, the plurality of mounting posts 5112 are arranged sequentially in a length direction X of the waterproof member 50 or a width direction Y of the waterproof member 50. Adjacent mounting posts 5112 of the plurality of mounting posts 5112 share one sidewall, and a sidewall of each of at least one of the plurality of mounting posts 5112 has a notch 51123 that penetrates an inner side and an outer side of the corresponding mounting post 5112 and is in communication with the corresponding insertion hole 51121. When the connection post 351 is inserted into the insertion hole 51121, the notch 51123 is configured to discharge air inside the insertion hole 51121, such that the connection post 351 is inserted to a bottom of the insertion hole 51121. In this way, connection stability between the connection post 351 and the insertion hole 51121 is good, and the connection stability between the button 30 and the waterproof member 50 is good.

Referring to FIG. 3 to FIG. 5, preferably, in some embodiments, at one waterproof sub-member 51 of the two waterproof sub-members 51, the notch 51123 is formed at each of the plurality of mounting posts 5112. An extending direction of the notch 51123 is the same as the length direction X of the waterproof member 50 or the width direction Y of the waterproof member 50.

In an embodiment, the plurality of mounting posts 5112 are arranged sequentially in the length direction X of the waterproof member 50, and extending directions of a plurality of notches 51123 are the same as the length direction X of the waterproof member 50. At this time, the plurality of notches 51123 may be in communication with each other, and may roughly form a straight line. During the process where the connection post 351 is inserted into the insertion hole 51121, air inside each insertion hole 51121 enters the notch 51123 disposed by the corresponding mounting post 5112. The air in the notch 51123 may flow through other notches 51123 and finally be discharged outside the waterproof member 50.

In another embodiment, the plurality of mounting posts 5112 are arranged sequentially in the width direction Y of the waterproof member 50, and the extending directions of the plurality of notches 51123 are the same as the width direction Y of the waterproof member 50. At this time, the plurality of notches 51123 may be in communication with each other, and may roughly form a straight line. During the process where the connection post 351 is inserted into the insertion hole 51121, the air inside each insertion hole 51121 enters the notch 51123 disposed by the corresponding mounting post 5112. The air in the notch 51123 may flow through the other notches 51123 and finally be discharged outside the waterproof member 50.

When each mounting post 5112 has a notch 51123, and the extending directions of the plurality of notches 51123 are the same as the length direction X or width direction Y of the waterproof member 50, it is possible to facilitate discharge of air from the plurality of insertion holes 51121 to an outside of the waterproof member 50. In this way, a connection between the connection post 351 and the insertion hole 51121 is relatively stable, and the connection strength between the button 30 and the waterproof member 50 is relatively high.

Referring to FIG. 2, FIG. 4, and FIG. 5, in some embodiments, the first side 33 of the button is provided with a thinned portion 331 located at a connection between two button regions 111 of the at least two button regions 111. The thinned portion 331 may be recessed from the first side 33 of the button toward the second side 35 of the button. When the user is in contact with the button 30 blindly, in response to the user triggering the thinned portion 331, the user may recognize that the triggered thinned portion 331 is a middle position between the two trigger portions 31, which can facilitate determination of the positions of the two trigger portions 31 by the user and can press the trigger portions 31 accurately.

Referring to FIG. 6, the headphone system 10000 according to the embodiments of the present disclosure includes the headphone 1000 according to the above embodiments and a charging case 3000 configured to charge the headphone 1000. The charging case 3000 is provided with a charging compartment. When the headphone 1000 needs to be charged, the battery box of the headphone 1000 may be received in the charging compartment, and the charging case 3000 may charge the battery inside the battery box.

In the headphone system 10000 according to the embodiments of the present disclosure, the box body 10 and the button 30 are connected through the spacing portion 1132. The trigger portions 31 and the button regions 111 are spaced apart from each other. The spacing portion 1132 is located between two adjacent button regions 111. When the user presses one of the trigger portions 31, the button 30 may be rotatable around the spacing portion 1132 to bring the trigger portion 31 into contact with the corresponding button region 111, to regulate the function of the headphone 1000. When the button 30 rotates around the spacing portion 1132, the other trigger portion 31 may be spaced apart from the corresponding button region 111. Compared with the existing functional box assembly 100, the present disclosure is provided with the spacing portion 1132, which enables the trigger portions 31 to be pressed independently without the occurrence of the linkage between the two trigger portions 31. In this way, the problem where the two trigger portions 31 are simultaneously in contact with the corresponding button regions 111, making it impossible to regulate the function of the headphone 1000, can be avoided.

The technical features of the above embodiments can be combined arbitrarily. In order to make the description simple, not every possible combination of the technical features in the above embodiments is described. However, as long as there is no conflict between the combinations of the technical features, any combination of the technical features should be considered as falling within the scope of this specification. Meanwhile, other implementations can be derived from the above-described embodiments, so that structural and logical substitutions and changes can be made without departing from the scope of the present disclosure.

The above embodiments illustrate merely some implementations of the present disclosure. Although description of the above embodiments is specific and detailed, the description should not be construed as limitations on the scope of the present disclosure. It should be pointed out that, various modifications and improvements can be made by those skilled in the art without departing from the concept of the embodiments of the present disclosure, and shall fall within the protection scope of the present disclosure as defined by the claims as attached.

What is claimed is:

1. A functional box assembly, comprising:
a box body having a control region configured for installing a button, the control region being provided with at least two button regions; and
the button disposed in the control region, the button comprising at least two trigger portions corresponding to the at least two button regions, wherein the box body and the button are connected through a spacing portion such that the at least two trigger portions and the at least two button regions are spaced apart from each other,
wherein the spacing portion is located between two adjacent button regions of the at least two button regions, and the button is rotatable around the spacing portion to bring one of the at least two trigger portions into contact with a corresponding button region of the at least two button regions.

2. The functional box assembly according to claim 1, wherein the control region is provided with a supporting portion extending from a sidewall of the box body and defining a mounting hole, the supporting portion comprising a supporting body and the spacing portion protruding from the supporting body toward the button, wherein:
one spacing portion is provided, the one spacing portion spanning the control region in a width direction of the button; or
two spacing portions are provided, the two spacing portions being spaced apart from each other and arranged at the supporting body in the width direction of the button.

3. The functional box assembly according to claim 2, further comprising:
a waterproof member disposed in the control region, the waterproof member and the supporting body being integrally disposed through a two-color injection molding, an opening of the mounting hole being covered by the waterproof member, the opening toward an interior of the box body.

4. The functional box assembly according to claim 3, wherein a hardness of the waterproof member is less than a hardness of the box body.

5. The functional box assembly according to claim 4, wherein:
the waterproof member is made of polymer; and
the box body is made of polymer.

6. The functional box assembly according to claim 3, wherein the waterproof member comprises two waterproof sub-members connected to each other, wherein:
one of the two waterproof sub-members corresponds to one of the at least two button regions in a thickness direction of the button; and
when one of the at least two trigger portions is in contact with a corresponding button region of the at least two button regions, a corresponding waterproof sub-member of the two waterproof sub-members is deformed.

7. The functional box assembly according to claim 6, wherein each of the two waterproof sub-members comprises:
a first waterproof portion located in the mounting hole; and
a second waterproof portion surrounding and connected to a periphery of the first waterproof portion, the second waterproof portion being embedded in and connected to the supporting body,
wherein when a corresponding one of the at least two trigger portions apply a force to the first waterproof portion, the first waterproof portion is deformed under the force, and the second waterproof portion remains fixedly connected to the supporting body.

8. The functional box assembly according to claim 7, wherein the supporting body comprises a first protrusion and a second protrusion that are arranged in a stepped manner in the thickness direction of the button, the first protrusion being closer to an outside of the box body than the second protrusion, and the spacing portion being arranged at a side of the first protrusion, the side of the first protrusion being away from the second protrusion.

9. The functional box assembly according to claim 8, wherein the supporting body has an injection hole at least penetrating the second protrusion, and at least a portion of the second waterproof portion is located in the injection hole.

10. The functional box assembly according to claim 9, wherein:
the first protrusion comprises a protrusion body that is of annular shape and two protruding extension portions, the two protruding extension portions protruding from the protrusion body toward a center of the protrusion body, and the spacing portion being disposed at the two protruding extension portions; and
the second protrusion comprises a first sub-protrusion that is of annular shape, a second sub-protrusion that is of annular shape, and a connection sub-protrusion connecting the first sub-protrusion and the second sub-protrusion, wherein the first sub-protrusion, the connection sub-protrusion, and the second sub-protrusion are arranged in a length direction of the button, at least a portion of the connection sub-protrusion being opposite to the two protruding extension portions in the thickness direction of the button, and each of the first sub-protrusion, the connection sub-protrusion, and the second sub-protrusion having the injection hole.

11. The functional box assembly according to claim 10, wherein the injection hole comprises:
a first injection hole disposed at the first sub-protrusion and the second sub-protrusion, and at least a portion of the second waterproof portion is located in the first injection hole; and
a second injection hole disposed at the connection sub-protrusion, the second injection hole being located between the two waterproof sub-members, and at least a portion of a junction of the two waterproof sub-members is located in the second injection hole.

12. The functional box assembly according to claim 7, wherein:
the first waterproof portion comprises a first side and a second side that are opposite to each other in a thickness direction of the waterproof member, the first side of the first waterproof portion being closer to an outside of the box body than the second side of the first waterproof portion, the first side of the first waterproof portion comprising a mounting post, and the mounting post having an insertion hole; and
the button comprises a first side and a second side that are opposite to each other in the thickness direction of the button, the first side of the button being closer to the outside of the box body than the second side of the button, the second side of the button being provided with a connection post, and the connection post extending into the insertion hole of the mounting post when the button is mounted at the waterproof member.

13. The functional box assembly according to claim 12, wherein a center of the insertion hole is located at a length mid-plane and a width mid-plane of the waterproof sub-member.

14. The functional box assembly according to claim 12, wherein:
a plurality of mounting posts is provided, the plurality of mounting posts having a plurality of insertion holes; and
a plurality of connection posts is provided, the plurality of connection posts being inserted into the plurality of insertion holes, respectively.

15. The functional box assembly according to claim 14, wherein:
the plurality of mounting posts are arranged sequentially in a length direction of the waterproof member or a width direction of the waterproof member; and
adjacent mounting posts of the plurality of mounting posts share one sidewall, and a sidewall of each of at least one of the plurality of mounting posts having a notch that penetrates an inner side and an outer side of the corresponding mounting post and is in communication with the corresponding insertion hole.

16. The functional box assembly according to claim 15, wherein at one waterproof sub-member of the two waterproof sub-members, the notch is disposed at each of the plurality of mounting posts, an extending direction of the notch being the same as the length direction of the waterproof member or the width direction of the waterproof member.

17. The functional box assembly according to claim 12, wherein the first side of the button is provided with a thinned portion located at a connection between two button regions of the at least two button regions.

18. A headphone, comprising a functional box assembly, wherein the functional box assembly comprises:
a box body having a control region configured for installing a button, the control region being provided with at least two button regions; and
the button disposed in the control region, the button comprising at least two trigger portions corresponding to the at least two button regions, wherein the box body and the button are connected through a spacing portion, such that the at least two trigger portions and the at least two button regions are spaced apart from each other,
wherein the spacing portion is located between two adjacent button regions of the at least two button regions, and the button is rotatable around the spacing portion to bring one of the at least two trigger portions into contact with a corresponding button region of the at least two button regions.

19. The headphone according to claim 18, comprising a bone conduction headphone and an air conduction headphone.

20. A headphone system, comprising a headphone and a charging case configured to charge the headphone, wherein the headphone comprises a functional box assembly, wherein the functional box assembly comprises:
a box body having a control region configured for installing a button, the control region being provided with at least two button regions; and
the button disposed in the control region, the button comprising at least two trigger portions corresponding to the at least two button regions, wherein the box body and the button are connected through a spacing portion, such that the at least two trigger portions and the at least two button regions are spaced apart from each other,
wherein the spacing portion is located between two adjacent button regions of the at least two button regions, and the button is rotatable around the spacing portion to bring one of the at least two trigger portions into contact with a corresponding button region of the at least two button regions.
